(19) United States
(12) Patent Application Publication
(10) Pub. No.: US 2025/0006525 A1
(43) Pub. Date: Jan. 2, 2025

(54) SUBSTRATE PROCESSING APPARATUS AND SUBSTRATE PROCESSING METHOD

(71) Applicant: Tokyo Electron Limited, Tokyo (JP)

(72) Inventors: Takeshi Tamura, Kikuchi-gun, Kumamoto (JP); Masaru Honda, Koshi-shi, Kumamoto (JP); Tatsuya Kitayama, Koshi-shi, Kumamoto (JP)

(21) Appl. No.: 18/712,802

(22) PCT Filed: Nov. 8, 2022
(86) PCT No.: PCT/JP2022/041468

§ 371 Date: May 23, 2024

(30) Foreign Application Priority Data
Nov. 25, 2021 (JP) 2021-190721

(51) Int. Cl. H01L 21/67; H01L 21/66; H01L 21/683

(52) U.S. Cl. CPC H01L 21/67253; H01L 21/67115; H01L 21/67259; H01L 21/6835; H01L 22/10; H01L 2221/68318

(57) ABSTRACT

A substrate processing apparatus includes a processing device 40; a measurement device 60; and a controller 31. The processing device 40 is configured to apply, in a combined substrate T in which an energy absorbing layer E is provided between a pair of substrates, at least one of thermal energy or light energy to the energy absorbing layer E to separate a first substrate from the combined substrate while holding a second substrate. The measurement device 60 is configured to measure a displacement of the first substrate in the processing device 40. The controller 31 is configured to control the devices. Further, the controller 31 determines, based on the displacement of the first substrate, whether the first substrate is separated.

### TECHNICAL FIELD

The various aspects and embodiments described herein pertain generally to a substrate processing apparatus and a substrate processing method.

### BACKGROUND

Recently, in a manufacturing process for a semiconductor device, a semiconductor substrate, such as a silicon wafer and a compound semiconductor wafer, is getting thinner while having a larger diameter. Such a thin large-diameter semiconductor substrate may be bent or broken when it is transferred or polished. To suppress this problem, the semiconductor substrate is transferred and polished after the semiconductor substrate is reinforced by bonding a support substrate thereto. Afterwards, the support substrate is separated from the semiconductor substrate (see Patent Document 1).

### PRIOR ART DOCUMENT

Patent Document 1: Japanese Patent Laid-open Publication No. 2014-060381

### DISCLOSURE OF THE INVENTION

### Problems to be Solved by the Invention

In view of the foregoing, the present disclosure provides a technique capable of efficiently performing a separating processing.

### Means for Solving the Problems

In one exemplary embodiment, a substrate processing apparatus includes a processing device; a measurement device; and a controller. The processing device is configured to apply, in a combined substrate in which an energy absorbing layer is provided between a pair of substrates, at least one of thermal energy or light energy to the energy absorbing layer to separate a first substrate from the combined substrate while holding a second substrate. The measurement device is configured to measure a displacement of the first substrate in the processing device. The controller is configured to control the devices. Further, the controller determines, based on the displacement of the first substrate, whether the first substrate is separated.

### Effects of the Invention

According to the present disclosure, it is possible to efficiently perform the separating processing.

### BRIEF DESCRIPTION OF THE DRAWINGS

FIG. 1 is a schematic plan view illustrating a configuration of a separating system according to an exemplary embodiment.

FIG. 2 is a schematic cross-sectional view of a combined substrate according to the exemplary embodiment.

FIG. 3 is a schematic view illustrating a configuration of a separating apparatus according to the exemplary embodiment.

FIG. 4 is a flowchart illustrating a processing sequence of a separating processing performed by the separating apparatus according to the exemplary embodiment.

FIG. 5 is a diagram illustrating an example of a transition of a distance from a laser displacement meter to an upper wafer.

FIG. 6 is a schematic cross-sectional view of a combined substrate according to a first modification example of the exemplary embodiment.

FIG. 7 is a schematic view illustrating a configuration of a separating apparatus according to the first modification example of the exemplary embodiment.

FIG. 8 is a flowchart illustrating a processing sequence of a separating processing performed by the separating apparatus according to the first modification example of the exemplary embodiment.

FIG. 9A and FIG. 9B are diagrams for explaining a separating processing according to a second modification example of the exemplary embodiment.

FIG. 10A and FIG. 10B are diagrams for explaining a separating processing according to a third modification example of the exemplary embodiment.

FIG. 11A to FIG. 11C are diagrams for explaining a separating processing according to a fourth modification example of the exemplary embodiment.

### DETAILED DESCRIPTION

Hereinafter, exemplary embodiments of a substrate processing apparatus and a substrate processing method according to the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships and different ratios.

Recently, in a manufacturing process for a semiconductor device, a semiconductor substrate, such as a silicon wafer and a compound semiconductor wafer, is getting thinner while having a larger diameter. Such a thin large-diameter semiconductor substrate may be bent or broken when it is transferred or polished.

To suppress this problem, the semiconductor substrate is transferred and polished after the semiconductor substrate is reinforced by bonding a support substrate thereto. Afterwards, the support substrate is separated from the semiconductor substrate. Also, in the separating processing, a combined substrate is surrounded by a chamber and a support substrate is separated from the combined substrate by heating the inside of the chamber.

Meanwhile, in the above-described prior art, the combined substrate is surrounded by the chamber, and, thus, whether or not the separating processing has been completed cannot be observed with the eyes. For this reason, a period of heating time with a sufficient margin is set in advance, and the separating processing is ended after a lapse of the period of heating time. Therefore, it is difficult to perform the separating processing with high efficiency for a sufficient period of time as required.

In this regard, there is a demand for a technique capable of overcoming the aforementioned problems, thus facilitating an efficient separating processing.

### <Configuration of Separating System>

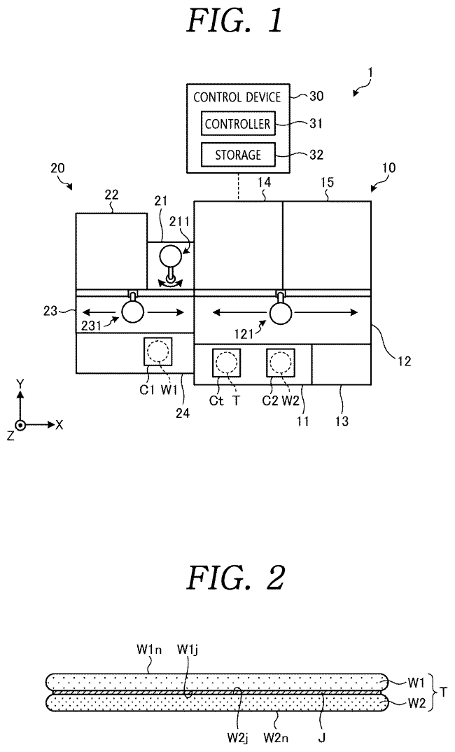

First, a configuration of a separating system 1 according to an exemplary embodiment will be described with reference to FIG. 1 and FIG. 2. FIG. 1 is a schematic plan view illustrating a configuration of a separating system 1 according to an exemplary embodiment. FIG. 2 is a schematic cross-sectional view of a combined substrate T according to the exemplary embodiment.

Hereinafter, in order to clarify positional relationships, the X-axis, the Y-axis and the Z-axis directions which are orthogonal to each other will be defined. The positive Z-axis direction will be regarded as a vertically upward direction.

The separating system 1 shown in FIG. 1 is configured to separate a first substrate W1 shown in FIG. 2 from a combined substrate T in which the first substrate W1 and a second substrate W2 are bonded to each other with an adhesive layer J therebetween. The first substrate W1 and the second substrate W2 are examples of substrates, and the adhesive layer J is an example of an energy absorbing layer. Also, the second substrate W2 is an example of one substrate, and the first substrate W1 is an example of the other substrate.

Hereinafter, the first substrate W1 will be referred to as “upper wafer W1,” and the second wafer W2 will be referred to as “lower wafer W2”. That is, the upper wafer W1 is an example of the first substrate, and the lower wafer W2 is an example of the second substrate.

In the following description, as shown in FIG. 2, among surfaces of the upper wafer W1, a surface to be bonded to the lower wafer W2 will be referred to as “bonding surface W1j”, and a surface opposite to the bonding surface W1j will be referred to as “non-bonding surface W1n”. Further, among surfaces of the lower wafer W2, a surface to be bonded to the upper wafer W1 will be referred to as “bonding surface W2j”, and a surface opposite to the bonding surface W2j will be referred to as “non-bonding surface W2n”.

The first substrate W1 is, for example, a semiconductor substrate, such as a silicon wafer or a compound semiconductor wafer, on which a plurality of electronic circuits is formed. Further, the second substrate W2 is, for example, a bare wafer on which no electronic circuit is formed. The first substrate W1 and the second substrate W2 have the substantially same diameter. Further, the second substrate W2 may have an electronic circuit formed thereon.

The adhesive layer J is disposed between the bonding surface W1j of the first substrate W1 and the bonding surface W2j of the second substrate W2. The adhesive layer J has a reduced adhesion when it is, for example, thermally foamed.

As shown in FIG. 1, the separating system 1 has two processing blocks: a first processing block 10 and a second processing block 20. The first processing block 10 and the second processing block 20 are disposed adjacent to each other.

In the first processing block 10, carrying-in of the combined substrate T, separating of the combined substrate T, and cleaning and carrying-out of the lower wafer W2 after being separated are performed. The first processing block 10 includes a carry-in/out station 11, a first transfer section 12, a standby station 13, a separation station 14, and a first cleaning station 15.

The carry-in/out station 11, the standby station 13, the separation station 14, and the first cleaning station 15 are disposed adjacent to the first transfer section 12. Specifically, the carry-in/out station 11 and the standby station 13 are arranged on the negative Y-axis side of the first transfer section 12, and the separation station 14 and the first cleaning station 15 are arranged on the positive Y-axis side of the first transfer section 12.

A plurality of cassette placing tables is provided in the carry-in/out station 11, and a cassette Ct accommodating therein the combined substrate T and a cassette C2 accommodating therein the lower wafer W2 after being separated are respectively placed on the cassette placing tables.

A first transfer device 121 configured to transfer the combined substrate T or the lower wafer W2 after being separated is disposed in the first transfer section 12. The first transfer device 121 is equipped with: a transfer arm configured to be movable in a horizontal direction, movable up and down in a vertical direction, and pivotable about a vertical direction; and a substrate holder provided on a leading end of the transfer arm.

In the first transfer section 12, a processing of transferring the combined substrate T to the standby station 13 and the separation station 14 and a processing of transferring the lower wafer W2 after being separated to the first cleaning station 15 and the carry-in/out station 11 are performed by the first transfer device 121.

In the standby station 13, a standby processing of allowing the combined substrate T to temporarily stand by before being subjected to a processing is performed when necessary. A placing table, on which the combined substrate T transferred by the first transfer device 121 is placed, is disposed in this standby station 13.

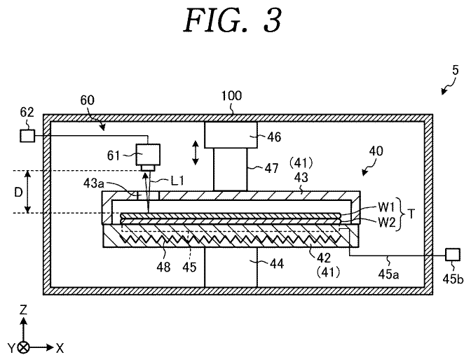

In the separation station 14, a separating apparatus 5 (see FIG. 3) is disposed, and a separating processing of separating the upper wafer W1 from the combined substrate T is performed by the separating apparatus 5. The separating apparatus 5 is an example of a substrate processing apparatus. A specific configuration and operation of the separating apparatus 5 will be described later.

In the first cleaning station 15, a cleaning processing on the lower wafer W2 after being separated is performed. In the first cleaning station 15, a first cleaning apparatus configured to clean the lower wafer W2 after being separated is disposed. As the first cleaning apparatus, one described in, for example, Japanese Patent Laid-open Publication No. 2013-033925 may be used.

In the second processing block 20, cleaning and carrying-out of the upper wafer W1 after being separated are performed. The second processing block 20 is equipped with a delivery station 21, a second cleaning station 22, a second transfer section 23, and a carry-out station 24. The second cleaning station 22 is an example of a cleaning apparatus.

The delivery station 21, the second cleaning station 22, and the carry-out station 24 are arranged adjacent to the second transfer section 23. Specifically, the delivery station 21 and the second cleaning station 22 are arranged on the positive Y-axis side of the second transfer section 23, and the carry-out station 24 is disposed on the negative Y-axis side of the second transfer section 23.

The delivery station 21 is disposed adjacent to the separation station 14 of the first processing block 10. In the delivery station 21, a delivery processing of receiving the separated upper wafer W1 from the separation station 14 and handing it over to the second cleaning station 22 is performed.

A second transfer device 211 is disposed in the delivery station 21. The second transfer device 211 has a non-contact holder, such as a Bernoulli chuck. The upper wafer W1 after being separated is transferred in a non-contact manner by the second transfer device 211.

In the second cleaning station 22, a second cleaning processing of cleaning the separated upper wafer W1 is performed. A second cleaning apparatus configured to clean the separated upper wafer W1 is disposed in the second cleaning station 22. As the second cleaning apparatus, one described in, for example, Japanese Patent Laid-open Publication No. 2013-033925 may be used.

A third transfer device 231 configured to transfer the separated upper wafer W1 is disposed in the second transfer section 23. The third transfer device 231 is equipped with: a transfer arm configured to be movable in a horizontal direction, movable up and down in a vertical direction, and pivotable about a vertical axis; and a substrate holder provided on a leading end of the transfer arm. In the second transfer section 23, a processing of transferring the separated upper wafer W1 to the carry-out station 24 is performed by the third transfer device 231.

A plurality of cassette placing tables is provided in the carry-out station 24, and a cassette C1 accommodating therein the separated upper wafer W1 is placed on each of the cassette placing tables.

Further, the separating system 1 is equipped with a control device 30. The control device 30 controls an operation of the separating system 1. The control device 30 is, for example, a computer, and includes a controller 31 and a storage 32. The storage 32 stores therein a program for controlling various processings, such as a bonding processing. The controller 31 controls the operation of the separating system 1 by reading and executing the program stored in the storage 32.

The program may be recorded on a computer-readable recording medium and installed from this recording medium to the storage 32 of the control device 30. The computer-readable recording medium may be, for example, a hard disk (HD), a flexible disk (FD), a compact disk (CD), a magnet optical disk (MO), or a memory card.

In the separating system 1 configured as described above, the first transfer device 121 of the first processing block 10 first takes out the combined substrate T from the cassette Ct disposed in the carry-in/out station 11, and carries the taken combined substrate T into the standby station 13.

For example, when the combined substrate T needs to stand by before being subjected to a processing due to a difference in processing time between the apparatuses, the combined substrate T may be temporarily placed on standby by using a temporary standby unit provided in the standby station 13. Thus, a loss time between a series of processes can be shortened.

Then, the combined substrate T is taken out from the standby station 13 by the first transfer device 121 and carried into the separation station 14. Thereafter, the separating apparatus 5 disposed in the separation station 14 performs the separating processing on the combined substrate T. By the separating processing, the combined substrate T is separated into the upper wafer W1 and the lower wafer W2.

The lower wafer W2 after being separated is taken out from the separation station 14 by the first transfer device 121 and carried into the first cleaning station 15. In the first cleaning station 15, the first cleaning apparatus performs a first cleaning processing on the lower wafer W2 after being separated. By the first cleaning processing, the bonding surface W2j of the lower wafer W2 is cleaned.

The lower wafer W2 after being subjected to the first cleaning processing is taken out from the first cleaning station 15 by the first transfer device 121, and is accommodated in the cassette C2 disposed in the carry-in/out station 11. Thereafter, the cassette C2 is taken out from the carry-in/out station 11 and collected. In this way, the processing upon the lower wafer W2 is ended.

Meanwhile, in the second processing block 20, processings upon the upper wafer W1 after being separated are performed in parallel with the above-described processings in the first processing block 10.

In the second processing block 20, the second transfer device 211 disposed in the delivery station 21 first takes out the separated upper wafer W1 from the separation station 14, and carries it into the second cleaning station 22.

Here, a top surface, i.e., the non-bonding surface W1n, of the separated upper wafer W1 is held by the separating apparatus 5, and the second transfer device 211 holds the bonding surface W1j side of the upper wafer W1 from below in a non-contact manner. Thereafter, the second transfer device 211 turns the held upper wafer W1 upside down, and then places it in the second cleaning apparatus of the second cleaning station 22.

Accordingly, the upper wafer W1 is placed in the second cleaning apparatus with its bonding surface W1j facing upwards. Then, the second cleaning apparatus performs a second cleaning processing of cleaning the bonding surface W1j of the upper wafer W1. By the second cleaning processing, the bonding surface W1j of the upper wafer W1 is cleaned.

The upper wafer W1 after being subjected to the second cleaning processing is taken out from the second cleaning station 22 by the third transfer device 231 disposed in the second transfer section 23, and accommodated in the cassette C1 disposed in the carry-out station 24. Thereafter, the cassette C1 is taken out from the carry-out station 24 and collected. In this way, the processing upon the upper wafer W1 is ended.

As described above, the separating system 1 according to the exemplary embodiment includes a front end for the combined substrate T and the lower wafer W2 after being separated, and a front end for the upper wafer W1 after being separated.

Here, the front end for the combined substrate T and the lower wafer W2 after being separated includes the carry-in/out station 11 and the first transfer device 121, and the front end for the upper wafer W1 after being separated includes the carry-out station 24 and the third transfer device 231.

With this configuration, the processing of transferring the upper wafer W1 to the carry-in/out station 11 can be performed in parallel with the processing of transferring the lower wafer W2 to the carry-out station 24. Therefore, a series of substrate processings can be performed efficiently.

Furthermore, in the separating system 1 according to the exemplary embodiment, the separation station 14 and the second cleaning station 22 are connected to each other with the delivery station 21 interposed therebetween. Accordingly, it becomes possible to directly carry the separated upper wafer W1 out of the separation station 14 into the second cleaning station 22 without passing through the first transfer section 12 and the second transfer section 23. Therefore, the upper wafer W1 after being separated can be transferred smoothly.

### <Configuration of Separating Apparatus>

Hereinafter, a configuration of the separating apparatus 5 provided in the separation station 14 will be described with reference to FIG. 3. FIG. 3 is a schematic view illustrating a configuration of the separating apparatus 5 according to the exemplary embodiment.

As depicted in FIG. 3, the separating apparatus 5 is equipped with a processing chamber 100. Carry-in/out openings (not shown) are provided at side surfaces of the processing chamber 100. The carry-in/out openings are respectively provided at the side of the first transfer section 12 (see FIG. 1) and at the side of the delivery station 21 (see FIG. 1).

The separating apparatus 5 includes a processing device 40 and a measurement device 60, which are disposed inside the processing chamber 100. Also, the processing device 40 according to the exemplary embodiment is equipped with a heating chamber 41.

The heating chamber 41 is equipped with a holder 42 and a cover 43, and a space formed between the holder 42 and the cover 43 may have a sealed structure. The holder 42 is configured to hold the lower wafer W2 side of the combined substrate T. The holder 42 is formed into a circular disc shape made of a metal member, such as aluminum, and supported by a column member 44 provided thereunder.

An attraction surface 45 is provided on a top surface of the holder 42. The attraction surface 45 is a porous body and is made of a resin member, such as PCTFE (polychlorotrifluoroethylene).

A suction space (not shown) is formed inside the holder 42 to communicate with the outside through the attraction surface 45. The suction space is connected to an air suction device 45b, such as a vacuum pump, via a suction line 45a. The holder 42 attracts the non-bonding surface W2n (see FIG. 2) of the lower wafer W2 on the attraction surface 45 by using a negative pressure generated by an air suction of the air suction device 45b. Thus, the combined substrate T is attracted to and held by the holder 42.

The cover 43 has, for example, a substantially cylindrical shape with an open bottom. The cover 43 is supported by a driving mechanism 46 attached to a ceiling portion of the processing chamber 100 with a column member 47 interposed therebetween. The driving mechanism 46 moves the cover 43 up and down by moving the support member 47 in the vertical direction.

Further, the controller 31 (see FIG. 1) causes the driving mechanism 46 to move the cover 43 down and bring the opening of the cover 43 into contact with a peripheral portion of the holder 42. Thus, the heating chamber 41 can have a sealed structure.

Furthermore, the controller 31 moves the cover 43 up to separate the cover 43 from the holder 42. Thus, the combined substrate T may be accommodated in the heating chamber 41, and the upper wafer W1 and the lower wafer W2 after being separated may be taken out from the heating chamber 41.

Also, the heating chamber 41 is equipped with a heater 48. The heater 48 is provided, for example, inside the holder 42. The controller 31 may increase an internal temperature of the heating chamber 41 to a desired temperature by operating the heater 48.

FIG. 3 illustrates the example where the heater 48 is provided in the holder 42, but the present disclosure is not limited thereto. For example, the heater 48 may be provided in the cover 43, or may be provided in both the holder 42 and the cover 43. Further, in the present disclosure, a separate heating source may be provided outside the heating chamber 41, and the inside of the heating chamber 41 may be heated by thermal energy supplied from this heating source.

The measurement device 60 of the separating apparatus 5 is configured to measure a displacement of the upper wafer W1 in the processing device 40. The measurement device 60 according to the exemplary embodiment is equipped with a laser displacement meter 61 and a distance measuring device 62. The laser displacement meter 61 is disposed, for example, above the cover 43 inside the processing chamber 100. That is, the laser displacement meter 61 is disposed outside the heating chamber 41.

The laser displacement meter 61 is configured to irradiate the upper wafer W1 of the combined substrate T held by the holder 42 with a laser light L1 via a transparent window member 43a provided in the cover 43, and configured to receive reflected light of the laser light L1 from the upper wafer W1.

The distance measuring device 62 is connected to the laser displacement meter 61, and is configured to measure a distance D from the laser displacement meter 61 to the upper wafer W1 based on the laser light L1 radiated from the laser displacement meter 61 and the light reflected from the upper wafer W1, which is received by the laser displacement meter 61.

### <Operation of Separating Apparatus>

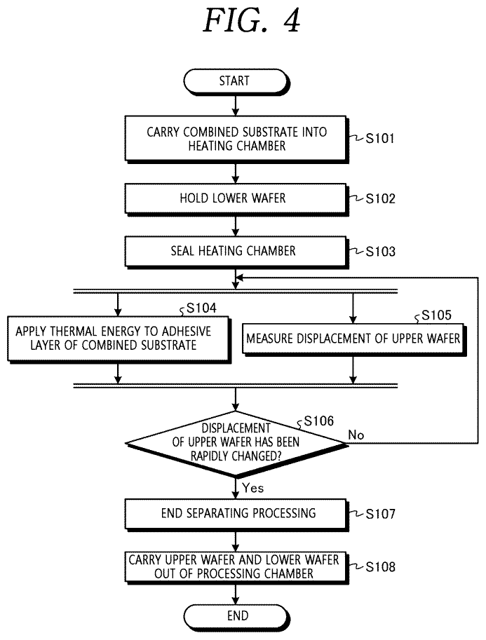

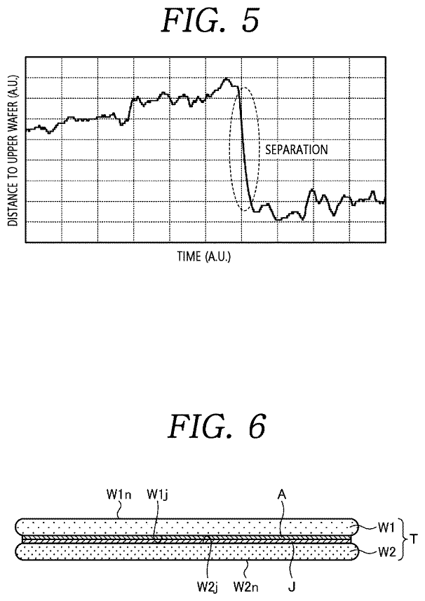

Hereinafter, an operation of the separating apparatus 5 according to the exemplary embodiment will be described in detail with reference to FIG. 4 and FIG. 5. FIG. 4 is a flowchart illustrating a processing sequence of a separating processing performed by the separating apparatus 5 according to the exemplary embodiment.

First, the controller 31 carries the combined substrate T into the heating chamber 41 of the processing chamber 100 (process S101). Then, the controller 31 operates the air suction device 45b to hold the lower wafer W2 of the combined substrate T by the holder 42 (process S102).

Thereafter, the controller 31 moves the cover 43 down to seal the heating chamber 41 (process S103). Thus, an internal temperature of the heating chamber 41 can be increased efficiently. Therefore, a separating processing on the combined substrate T can be performed efficiently.

In the present disclosure, the process S103 may be performed before the process S102 or in parallel with the process S102.

Then, the controller 31 operates the heater 48 to increase the internal temperature of the heating chamber 41 to a predetermined temperature. Thus, thermal energy is applied to the adhesive layer J of the combined substrate T (process S104). For example, the controller 31 heats the inside of the heating chamber 41 to about 450° C.

Then, a state of the adhesive layer J is changed (e.g., foamed) by the thermal energy, and, thus, the adhesion of the adhesive layer J is decreased. Therefore, the upper wafer W1 begins to be separated from the combined substrate T.

The controller 31 operates the measurement device 60 to measure the displacement of the upper wafer W1 (process S105) in parallel with the process S104. For example, in the exemplary embodiment, the controller 31 measures the distance D from the laser displacement meter 61 to the upper wafer W1 as the displacement of the upper wafer W1.

Further, the controller 31 detects the displacement (distance D) of the upper wafer W1 in real time over a period of time as shown in FIG. 5. FIG. 5 is a diagram illustrating an example of a transition of the distance D from the laser displacement meter 61 to the upper wafer W1.

Then, the controller 31 determines whether the displacement (distance D) of the upper wafer W1 has been rapidly changed (process S106). For example, in the exemplary embodiment, the controller 31 continuously measures a difference between a moving average value of the displacements (distances D) of the first wafer W1 at respective time points during the separating processing and a moving average value of the displacements (distances D) of the first wafer W1 right before the time points.

When a difference between a moving average value of the displacements (distances D) of the first wafer W1 at a certain time point and a moving average value of the displacements (distances D) of the first wafer W1 right before the time point is greater than a predetermined value, the controller 31 determines that the second wafer W2 is separated from the combined substrate T at that time point. The predetermined value is, for example, about several tens of micrometers (μm).

That is, when the displacement (distance D) of the upper wafer W1 is rapidly changed (process S106, Yes), the controller 31 determines that the second wafer W2 has been separated from the combined substrate T, and ends the separating processing (process S107).

Then, the controller 31 carries the upper wafer W1 and the lower wafer W2 out of the processing chamber 100 (process S108), and ends the processing. Meanwhile, when the displacement (distance D) of the upper wafer W1 is not rapidly changed (process S106, No), the controller 31 returns to the processes S104 and S105.

In the example shown in FIG. 5, the adhesive layer J is foamed to be inflated, and, thus, the thickness of the combined substrate T is rapidly increased. Therefore, the separation of the first wafer W1 is completed. That is, when the separation is completed, the distance D from the laser displacement meter 61 to the upper wafer W1 is rapidly decreased.

As described above, in the exemplary embodiment, whether or not the separating processing has been completed is determined based on the displacement (distance D) of the first wafer W1 that is not held on the combined substrate T on which the second wafer W2 is held and the separating processing is performed.

Thus, the completion of the separation of the upper wafer W1 can be detected with high precision. At that time point, the separating processing (herein, thermal treatment in the heating chamber 41) can be ended.

Therefore, according to the exemplary embodiment, it is possible to suppress the use of spare time for the separating processing. Thus, it is possible to efficiently perform the separating processing.

Further, in the exemplary embodiment, when the displacement (distance D) of the upper wafer W1 has been rapidly changed, it can be determined that the upper wafer W1 has been separated. Thus, the completion of the separation of the upper wafer W1 can be rapidly detected. Therefore, it is possible to more efficiently perform the separating processing.

Furthermore, the exemplary embodiment has been described for the example where it is determined whether the displacement of the upper wafer W1 has been rapidly changed, based on the difference between the moving average value of the displacements (distances D) of the first wafer W1 at respective time points during the separating processing and the moving average value of the displacements (distances D) of the first wafer W1 right before the time points. However, the present disclosure is not limited thereto. Whether or not the displacement of the upper wafer W1 has been rapidly changed may be determined by various methods known in the art.

Also, the exemplary embodiment has been described for the example where the distance D from the laser displacement meter 61 to the upper wafer W1 is used as the displacement of the upper wafer W1. However, the present disclosure is not limited thereto. For example, a relative position of the upper wafer W1 with respect to another reference point may be used as the displacement of the upper wafer W1.

Further, in the exemplary embodiment, the measurement device 60 measures the displacement of the upper wafer W1 in the non-contact manner. Thus, it is possible to suppress damage to the upper wafer W1.

Furthermore, the exemplary embodiment has been described for the example where the measurement device 60 measures the displacement of the upper wafer W1 by the laser displacement meter 61. However, the present disclosure is not limited thereto.

For example, the measurement device 60 may measure the displacement of the upper wafer W1 by an ultrasonic displacement meter or a camera. Also, when the displacement of the upper wafer W1 is measured by the camera, the camera may be disposed at a lateral side of the combined substrate T.

Moreover, in the exemplary embodiment, the measurement device 60 measures the displacement of the upper wafer W1 via the window member 43a of the cover 43. Thus, it is possible to measure the displacement of the upper wafer W1 while maintaining airtightness around the combined substrate T. Therefore, the separating processing time for the combined substrate T can be further shortened.

Therefore, according to the exemplary embodiment, it is possible to more efficiently perform the separating processing.

### First Modification Example

Hereinafter, various modification examples of the exemplary embodiment will be described with reference to FIG. 6 to FIG. 11C. FIG. 6 is a schematic cross-sectional view of a combined substrate T according to a first modification example of the exemplary embodiment. As shown in FIG. 6, the combined substrate T of the first modification example is different from the combined substrate T of the exemplary embodiment in that an ablation layer A is disposed between the adhesive layer J and the first wafer W1.

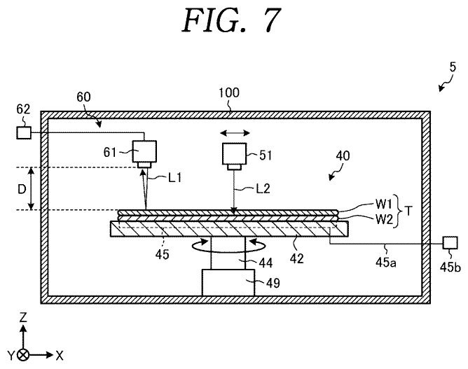

The ablation layer A is another example of the energy absorbing layer, and is melted and evaporated by absorbing a laser light L2 (see FIG. 7) radiated from a laser radiator 51 (see FIG. 7). The ablation layer A is composed of, for example, an LTHC (Light to Heat Conversion) film or an Al (aluminum) film.

FIG. 7 is a schematic view illustrating a configuration of a separating apparatus 5 according to the first modification example of the exemplary embodiment. As shown in FIG. 7, the separating apparatus 5 of the first modification example includes the processing device 40 and the measurement device 60 as in the exemplary embodiment.

Also, the processing device 40 of the first modification example is equipped with the holder 42 which is rotatable by a driving mechanism 49, and the laser radiator 51. The holder 42 attracts the non-bonding surface W2n (see FIG. 6) of the lower wafer W2 to the attraction surface 45 by using a negative pressure generated by an air suction of the air suction device 45b. Thus, the combined substrate T is attracted to and held by the holder 42.

The laser radiator 51 is disposed above the holder 42 and movable in the horizontal direction. Also, the laser radiator 51 is configured to radiate the laser light L2 downwards. The laser light L2 has, for example, top-hat distribution with more uniform energy distribution than Gaussian distribution.

Further, the controller 31 controls the laser radiator 51 to sweep and radiate the laser light L2 toward the ablation layer A (see FIG. 6) of the combined substrate T held by the holder 42. Thus, all of the ablation layer A is cut off, and the first wafer W1 is separated from the combined substrate T.

That is, in the first modification example, the first wafer W1 is separated from the combined substrate T by applying light energy to the ablation layer A.

Also, the laser displacement meter 61 of the first modification example is placed under the same environment as the laser radiator 51, and configured to radiate the laser light L1 toward the upper wafer W1 of the combined substrate T held by the holder 42 and receive reflected light of the laser light L1 from the upper wafer W1. Thus, the measurement device 60 measures the distance D from the laser displacement meter 61 to the upper wafer W1.

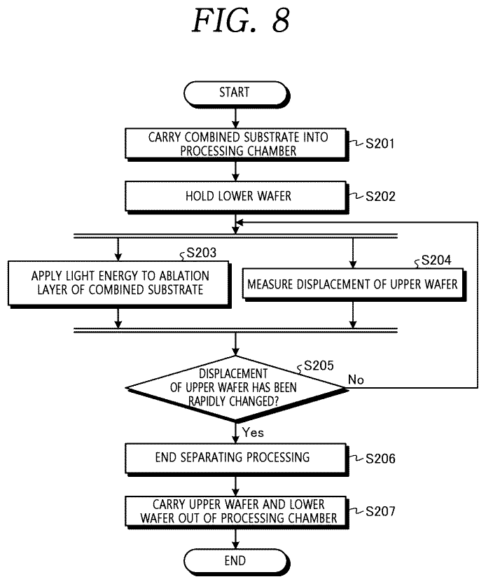

FIG. 8 is a flowchart illustrating a processing sequence of a separating processing performed by the separating apparatus 5 according to the first modification example of the exemplary embodiment. First, the controller 31 carries the combined substrate T into the processing chamber 100 (process S201). Then, the controller 31 operates the air suction device 45b to hold the lower wafer W2 of the combined substrate T by the holder 42 (process S202).

Thereafter, the controller 31 operates the laser radiator 51 to apply light energy to the ablation layer A of the combined substrate T (process S203). Further, the controller 31 operates the measurement device 60 to measure the displacement of the upper wafer W1 (process S204) in parallel with the process S203. For example, in the first modification example, the controller 31 measures the distance D from the laser displacement meter 61 to the upper wafer W1 as the displacement of the upper wafer W1.

Then, the controller 31 determines whether the displacement (distance D) of the upper wafer W1 has been rapidly changed (process S205). When the displacement (distance D) of the upper wafer W1 is rapidly changed (process S205, Yes), the controller 31 determines that the second wafer W2 has been separated from the combined substrate T, and ends the separating processing (process S206).

Then, the controller 31 carries the upper wafer W1 and the lower wafer W2 out of the processing chamber 100 (process S207), and ends the processing. Meanwhile, when the displacement (distance D) of the upper wafer W1 is not rapidly changed (process S205, No), the controller 31 returns to the processes S203 and S204.

In the first modification example, the thickness of the combined substrate T is rapidly decreased by, for example, cutting off the ablation layer A, and, thus, the separation of the first wafer W1 is completed. Therefore, when the separation is completed, the distance D from the laser displacement meter 61 to the upper wafer W1 is rapidly increased.

As described above, in the first modification example as in the exemplary embodiment, whether or not the separating processing has been completed is determined based on the displacement (distance D) of the first wafer W1 that is not held on the combined substrate T on which the second wafer W2 is held and the separating processing is performed.

Thus, the completion of the separation of the upper wafer W1 can be detected with high precision. At that time point, the separating processing (herein, laser radiation by the laser radiator 51) can be ended.

Therefore, according to the first modification example, it is possible to suppress the use of spare time for the separating processing. Thus, it is possible to efficiently perform the separating processing.

Further, the first modification example has been described for the example where the first wafer W1 is separated by irradiating the ablation layer A between the first wafer W1 and the second wafer W2 with the laser light L2. However, the present disclosure is not limited thereto.

For example, a silicon oxide film is formed on each of the bonding surface W1j of the first wafer W1 and the bonding surface W2j of the second wafer W2. In the combined substrate T in which the silicon oxide films are directly bonded to each other, a separating processing may be performed by irradiating the silicon oxide films, which serve as energy absorbing layers, with the laser light L2.

Even in this case, when the separating processing is ended, the thickness of the combined substrate T is rapidly changed. Thus, by measuring the displacement of the first wafer W1 with the measurement device 60, the completion of the separation of the upper wafer W1 can be detected with high precision.

Also, according to the present disclosure, a laser light L is radiated to the adhesive layer J of the combined substrate T shown in FIG. 2. Therefore, the state of the adhesive layer J is changed (e.g., foamed), and, thus, the upper wafer W1 can be separated from the combined substrate T.

Even in this case, when the separating processing is ended, the thickness of the combined substrate T is rapidly changed. Thus, by measuring the displacement of the first wafer W1 with the measurement device 60, the completion of the separation of the upper wafer W1 can be detected with high precision.

### Second Modification Example

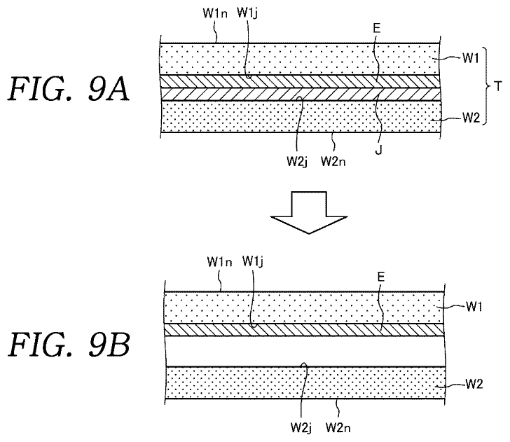

FIG. 9A and FIG. 9B are diagrams for explaining a separating processing according to a second modification example of the exemplary embodiment. As shown in FIG. 9A, in the second modification example, the adhesive layer J and an energy absorbing layer E are disposed between the first wafer W1 and the second wafer W2 forming the combined substrate T.

For example, in the second modification example, the adhesive layer J is disposed to come into contact with the bonding surface W2j of the second wafer W2 and the energy absorbing layer E is disposed to come into contact with the bonding surface W1j of the first wafer W1. The energy absorbing layer E serves to absorb at least one of thermal energy and light energy, and absorbs, for example, the laser light L2 (see FIG. 7) and generates heat.

Also, in the second modification example, the controller 31 (see FIG. 1) irradiates the energy absorbing layer E of the combined substrate T with the laser light L2. Thus, the temperature of the energy absorbing layer E is increased and the state of the adhesive layer J is changed (e.g., foamed). Therefore, the upper wafer W1 can be separated from the combined substrate T as shown in FIG. 9B.

Herein, in the second modification example, the energy absorbing layer E remains on the bonding surface W1j of the first wafer W1, whereas most of the adhesive layer J is removed from the bonding surface W2j of the second wafer W2. That is, in the second modification example, a layer which absorbs at least one of the thermal energy and the light energy (in this case, the energy absorbing layer E) is separately provided from a layer to be removed by the separating processing.

Even in this case, when the separating processing is ended, the thickness of the combined substrate T is rapidly changed. Thus, by measuring the displacement of the first wafer W1 with the measurement device 60 (see FIG. 7), the completion of the separation of the upper wafer W1 can be detected with high precision.

The second modification example is not limited to the case where the adhesive layer J is changed by allowing the energy absorbing layer E to absorb the light energy. The adhesive layer J may be changed by allowing the energy absorbing layer E to absorb the thermal energy.

### Third Modification Example

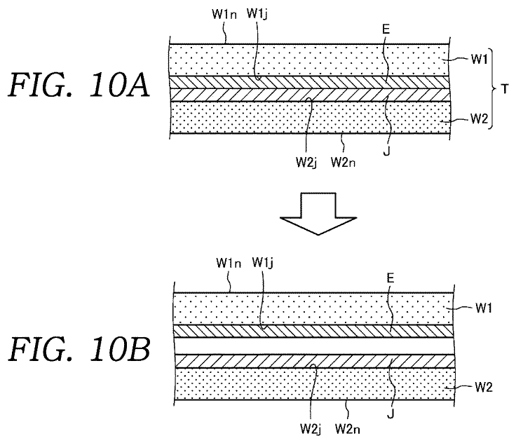

FIG. 10A and FIG. 10B are diagrams for explaining a separating processing according to a second modification example of the exemplary embodiment. As shown in FIG. 10A, in the third modification example as in the second modification example, the adhesive layer J and the energy absorbing layer E are disposed between the first wafer W1 and the second wafer W2 forming the combined substrate T.

In the third modification example, the controller 31 (see FIG. 1) radiates the energy absorbing layer E of the combined substrate T with the laser light L2. Thus, the temperature of the energy absorbing layer E is increased and the adhesion between the adhesive layer J and the energy absorbing layer E is decreased. Therefore, as shown in FIG. 10B, the upper wafer W1 is separated from the combined substrate T.

Herein, in the third modification example, the energy absorbing layer E remains on the bonding surface W1j of the first wafer W1, and the adhesive layer J also remains on the bonding surface W2j of the second wafer W2.

Even in this case, when the separating processing is ended, the thickness of the combined substrate T is rapidly changed. Thus, by measuring the displacement of the first wafer W1 with the measurement device 60 (see FIG. 7), the completion of the separation of the upper wafer W1 can be detected with high precision.

The third modification example is not limited to the case where the adhesion between the adhesive layer J and the energy absorbing layer E is decreased by allowing the energy absorbing layer E to absorb the light energy. For example, in the third modification example, the adhesion between the adhesive layer J and the energy absorbing layer E may be decreased by allowing the energy absorbing layer E to absorb the thermal energy.

### Fourth Modification Example

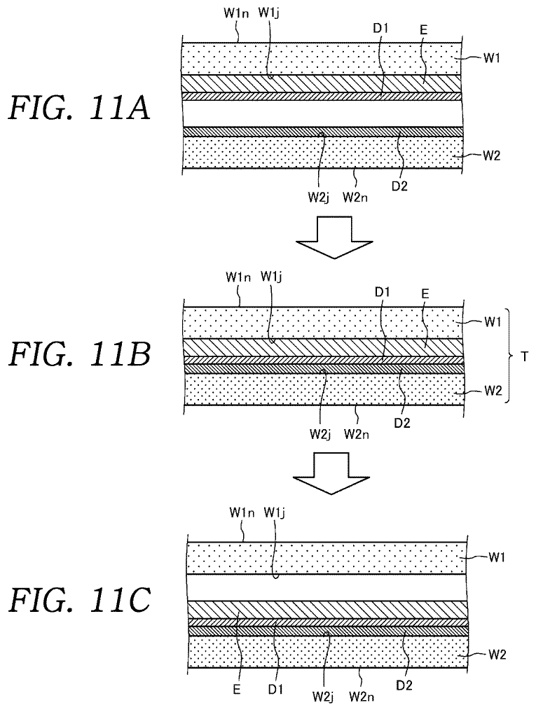

FIG. 11A to FIG. 11C are diagrams for explaining a separating processing according to a fourth modification example of the exemplary embodiment. As shown in FIG. 11A, in the fourth modification example, a first device layer D1 is formed on the bonding surface W1j of the first wafer W via the energy absorbing layer E. Also, a second device layer D2 is formed on the bonding surface W2j of the second wafer W2.

In the fourth modification example, the first device layer D1 and the second device layer D2 are bonded to each other by a technique known in the art, and, thus, the combined substrate T is formed as shown in FIG. 11B.

Further, in the fourth modification example, the controller 31 (see FIG. 1) irradiates the energy absorbing layer E of the combined substrate T with the laser light L2. Thus, the temperature of the energy absorbing layer E is increased and the adhesion between the first wafer W1 and the energy absorbing layer E is decreased. Therefore, as shown in FIG. 11C, the upper wafer W1 is separated from the combined substrate T.

Herein, in the fourth modification example, the second device layer D1, the first device layer D1, and the adhesive layer J remain on the bonding surface W2j of the second wafer W2.

Even in this case, when the separating processing is ended, the thickness of the combined substrate T is rapidly changed. Thus, by measuring the displacement of the first wafer W1 with the measurement device 60 (see FIG. 7), the completion of the separation of the upper wafer W1 can be detected with high precision.

The fourth modification example is not limited to the case where the adhesion between the first wafer W1 and the energy absorbing layer E is decreased by allowing the energy absorbing layer E to absorb the light energy. For example, in the third modification example, the adhesion between the first wafer W1 and the energy absorbing layer E may be decreased by allowing the energy absorbing layer E to absorb the thermal energy.

The substrate processing apparatus (the separating apparatus 5) according to the exemplary embodiment includes the processing device 40, the measurement device 60, and the controller 31. The processing device 40 applies at least one of thermal energy and light energy to the energy absorbing layer E (the adhesive layer J, the ablation layer A) to separate the other substrate (the first wafer W1) from the combined substrate T while holding one substrate (the second wafer W2). In the combined substrate T, the energy absorbing layer E (the adhesive layer J, the ablation layer A) is formed between a pair of substrates (the first wafer W1 and the second wafer W2). The measurement device 60 measures a displacement of the other substrate (the first wafer W1) in the processing device 40. The controller 31 controls each of the components. Further, the controller 31 determines whether the other substrate (the first wafer W1) has been separated based on the displacement of the other substrate (the first wafer W1). Thus, it is possible to efficiently perform the separating processing.

Furthermore, in the substrate processing apparatus (the separating apparatus 5) according to the exemplary embodiment, when the displacement of the other substrate (the first wafer W1) is rapidly changed, the controller 31 determines that the other substrate (the first wafer W1) has been separated. Thus, it is possible to more efficiently perform the separating processing.

Moreover, in the substrate processing apparatus (the separating apparatus 5) according to the exemplary embodiment, the measurement device 60 measures the displacement of the other substrate (the first wafer W1) in a non-contact manner. Thus, it is possible to suppress damage to the upper wafer W1.

Besides, in the substrate processing apparatus (the separating apparatus 5) according to the exemplary embodiment, the measurement device 60 includes at least one of the laser displacement meter 61, an ultrasonic displacement meter, and a camera. Thus, it is possible to suppress damage to the upper wafer W1.

Also, in the substrate processing apparatus (the separating apparatus 5) according to the exemplary embodiment, the processing device 40 includes the heating chamber 41 configured to apply thermal energy to the energy absorbing layer E (the adhesive layer J, the ablation layer A) and having a sealed structure. Further, the measurement device 60 measures the displacement of the other substrate (the first wafer W1) from the outside of the heating chamber 41. Thus, it is possible to more efficiently perform the separating processing.

Furthermore, in the substrate processing apparatus (the separating apparatus 5) according to the exemplary embodiment, the processing device 40 includes the laser radiator 51 configured to apply light energy to the energy absorbing layer E (the adhesive layer J, the ablation layer A). Moreover, the measurement device 60 is placed under the same environment as the laser radiator 51. Thus, it is possible to efficiently perform the separating processing.

Besides, the substrate processing method according to the exemplary embodiment includes the application processes S104 and S203, the measurement processes S105 and S204, and the determination processes S106 and S205. The application processes are performed by applying at least one of thermal energy and light energy to the energy absorbing layer E (the adhesive layer J, the ablation layer A) in the combined substrate T while holding one substrate (the second wafer W1). In the combined substrate T, the energy absorbing layer E (the adhesive layer J, the ablation layer A) is formed between a pair of substrates (the first wafer W1 and the second wafer W2). The measurement processes S105 and S204 are performed by measuring a displacement of the other substrate (the first wafer W1) in the application processes S104 and S203. The determination processes S106 and S205 are performed by determining whether the other substrate (the first wafer W1) has been separated based on the displacement of the other substrate (the first wafer W1). Thus, it is possible to efficiently perform the separating processing.

So far, the exemplary embodiment of the present disclosure has been described. However, the present disclosure is not limited to the above-described exemplary embodiment. Various changes may be made without departing from the sprit or scope of the subject matter presented herein. By way of example, although the above exemplary embodiment has been described for the example where the upper wafer W1 is separated from the combined substrate T, the present disclosure is not limited thereto. For example, the lower wafer W2 may be separated from the combined substrate T.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Separating system
5: Separating apparatus (example of substrate processing apparatus)
31: Controller
40: Processing device
41: Heating chamber
42: Holder
43: Cover
51: Laser radiator
60: Measurement device
61: Laser displacement meter
A: Ablation layer (example of energy absorbing layer)
D: Distance (example of displacement)
E: Energy absorbing layer
J: Adhesive layer (example of energy absorbing layer)
T: Combined substrate
W1: Upper wafer (substrate and example of the other substrate)
W2: Lower wafer (substrate and example of one substrate)

1. A substrate processing apparatus, comprising:
a processing device configured to apply, in a combined substrate in which an energy absorbing layer is provided between a pair of substrates, at least one of thermal energy or light energy to the energy absorbing layer to separate a first substrate from the combined substrate while holding a second substrate;
a measurement device configured to measure a displacement of the first substrate disposed in the processing device; and
a controller configured to control the devices,
wherein the controller determines, based on the displacement of the first substrate, whether the first substrate is separated.

2. The substrate processing apparatus of claim 1,
wherein when the displacement of the first substrate is rapidly changed, the controller determines that the first substrate is separated.

3. The substrate processing apparatus of claim 1,
wherein the measurement device measures the displacement of the first substrate in a non-contact manner.

4. The substrate processing apparatus of claim 1,
wherein the measurement device includes at least one of a laser displacement meter, an ultrasonic displacement meter, or a camera.

5. The substrate processing apparatus of claim 1,
wherein the processing device includes a heating chamber, having a sealed structure, configured to apply thermal energy to the energy absorbing layer, and
the measurement device measures the displacement of the first substrate from an outside of the heating chamber.

6. The substrate processing apparatus of claim 1,
wherein the processing device includes a laser radiator configured to apply light energy to the energy absorbing layer, and
the measurement device is placed under a same environment as the laser radiator.

7. A substrate processing method, comprising:
applying, in a combined substrate in which an energy absorbing layer is provided between a pair of substrates, at least one of thermal energy or light energy to the energy absorbing layer while holding a first substrate;
measuring a displacement of a second substrate in the applying of at least one of thermal energy or light energy; and
determining, based on the displacement of the second substrate, whether the second substrate is separated.
